(19) United States
(12) Patent Application Publication
(10) Pub. No.: US 2021/0384403 A1
(43) Pub. Date: Dec. 9, 2021

(54) Reinforced Bulk High Temperature Superconductors and Method for Their Manufacture

(71) Applicant: Cambridge Enterprise Limited, Cambridge, Cambridgeshire (GB)

(72) Inventors: Devendra Kumar Namburi, Cambridge (GB); Kysen G. Palmer, Cambridge (GB); Wayne Lau, Cambridge (GB); Yunhua Shi, Cambridge (GB); Anthony Dennis, Cambridge (GB); John Hay Durrell, Cambridge (GB); David Cardwell, Cambridge (GB)

(21) Appl. No.: 17/286,771

(22) PCT Filed: Oct. 21, 2019
(86) PCT No.: PCT/EP2019/078582

§ 371 Date: Apr. 19, 2021

Related U.S. Application Data
(60) Provisional application No. 62/766,485, filed on Oct. 22, 2018.

(30) Foreign Application Priority Data
Jun. 19, 2019 (GB) 1908788.1

(51) Int. Cl. H01L 39/12; H01L 39/24

(52) U.S. Cl. CPC H01L 39/126; H01L 39/2477

(57) ABSTRACT

A bulk superconductor device is disclosed, comprising a single grain RE-BCO element incorporating reinforcing fibres. The single grain (RE)BCO element comprises RE-211 pinning sites disposed in a RE-123 matrix and further comprises Ag. The reinforcing fibres comprise a ceramic such as SiC and a refractory metal such as W. The reinforcing fibres comprise a core formed of the refractory metal and a ceramic cladding surrounding the core. The device may be manufactured by a top seeded melt growth process or by a top seeded infiltration growth process.

### FIELD OF THE INVENTION

The present invention relates to bulk high temperature superconductors and methods for their manufacture. Of particular interest are rare earth barium copper oxide bulk superconductors with fibre reinforcement.

### BACKGROUND

High temperature superconducting oxides include rare-earth based barium copper oxides. For example, the composition YBa₂Cu₃O_{7-δ} (referred to herein and in the academic literature as YBCO) is a superconductor at temperatures below a critical temperature T_{c}, which varies with the value of δ. Rare-earth based (RE)-Ba—Cu—O ((RE)BCO) bulk superconductors in single grain form and typically with engineered microstructures have great potential to trap large magnetic fields due to their tremendous ability to pin magnetic flux vortices thereby enabling large supercurrents to flow within the size of the sample [1-9]. When an external magnetic field is applied and the material is field cooled, superconducting persistent currents are set circulating within the single grain size of the superconducting material. This effect is observed as a trapped field profile with a peak at the center and an associated field gradient is observed towards the sample edge, the slope of which is proportional to the critical current density (J_{c}) of the superconducting material. Put simply, the trapped field in the material is proportional to J_{c}*d, where d is the size of the single grain.

Over the last 30 years, extensive research has been carried out on these materials which led to the development of potential fabrication methodologies such as Top Seeded Melt Growth (TSMG) [10-16] and Top Seeded Infiltration Growth (TSIG) [17-28] techniques that enable reliable production of single grains out of these materials with success rates in excess of about 80-90%. These materials with suitable properties are key candidates for several real scale applications such as trapped field magnets, rotating electrical machines, flywheel energy storage systems, magnetic separators, fault current limiters and magnetic bearings [1-4, 29, 30].

(RE)BCO materials are type-II superconductors and are ceramic in nature. In order to achieve (RE)BCO single grains, precursor powders comprising a mixture of (RE)Ba₂Cu₃O₇₋ₓ (RE-123) and (RE)₂BaCuO₅ (RE-211), enriched with a grain refining agent such as Pt or CeO₂ are used. The RE-123 phase when heated above its peritectic temperature Tₚ melts incongruently and decomposes into a solid RE-211 phase and a barium-rich liquid phase (comprising BaCuO₂ and CuO). These RE-211 and liquid phases recombine to form RE-123 on subsequent cooling of the material below the Tₚ of the compound. This process would usually generate multiple grain nucleation sites, resulting in the formation of a multi-grained (RE)BCO. In this context, a seed crystal with Tₚ greater than that of the (RE)BCO material being grown, is arranged on the pressed powder sample (cold seeding method). On cooling of the sample, the seed crystal initiates heterogeneous nucleation and subsequent growth to form a single grain exhibiting characteristic growth-facet lines both in a-b plane and along c-axis.

Recent developments made in fabrication processes have enabled production of large single-grain bulk RE-Ba—Cu—O superconductors with enhanced J_{c} values. Some of the notable examples are the fabrication of 65 mm diameter GdBCO—Ag single grain bulk superconductor trapping a magnetic field of 3 T at 77 K [31], increasing the flux pinning strength of (RE)BCO with proper tuning of the microstructure to achieve optimum amounts of RE-211 phase in the matrix of RE-123 [5, 32, 33] and further with additional enhancement via suitable additives and/or dopants in (RE)BCO [34-36].

### SUMMARY OF THE INVENTION

Operating the (RE)BCO materials described above in either large magnetic fields or intensely in rotating patterns, or both, may be required in some real applications. However, the present inventors appreciate that the mechanical stresses to which these materials are subjected during the magnetization and subsequent operation are immense. It is found that bulk superconductors will fail mechanically when put under extreme tensile loading such as the tensile loading that is applied due to maintaining a magnetic field. For example, a magnetic field of 15 tesla can give rise to a hoop stress greater than about 100 MPa [37]. These materials are typically not reinforced, and in bare form (i.e. without reinforcement) these materials cannot withstand magnetic fields of greater than 7-8 T [38-41] even at low temperatures due to the enormous tensile forces that are generated as a result of Lorentz forces.

The material failure method for the type of loading discussed above is often a rapid failure of the superconductor and destructive strain within the bulk material [42]. A bulk superconductor that has failed due to destructive strain and subsequent cracking will be incapable of maintaining the original magnetic field magnitude due to the reduction in effective current loop size. An example of the effect of such destructive strain is shown in FIG. 1. FIG. 1 shows the trapped field profile measured at 77 K in an YBCO sample which was earlier subjected to a large magnetic field of 18 T. As clearly shown in FIG. 1, the material has cracked close to the centre, giving rise to two grains with greatly reduced trapped field performance.

Further, when two single grains are stacked one on the other, the magnetic field experienced at the center of the sample stack is large. Some of the examples which illustrate the great potential of the (RE)BCO superconducting bulk materials in trapping large magnetic fields are: 16 Tat 24 K achieved in 2002 [43], 17.24 Tat 29 K achieved in 2003 [44] and the current record magnetic field of 17.6 Tat 26 K achieved in 2014 [2]. All these results were possible only because of the fact that these materials were reinforced in one way or another. Some of the reinforcement techniques followed are complex resin impregnation or pre-stressing via a shrink-fit technique or a combination of both.

In the view of the present inventors, even when employing these complex reinforcing configurations, the success rate for samples that can trap large magnetic fields is limited due to the rather low tensile strength of the material.

Efforts have been made to improve mechanical strength of these materials. Addition of silver (whose melting point is lower than the Tₚ of (RE)BCO, thereby addressing unwanted nucleation/sub-grain problems) has helped in improving the mechanical strength of (RE)BCO as the silver partially fills the pores and cracks present in the ceramic material and thereby helps to prevent crack initiations and propagations to some extent when the material is exposed to large magnetic fields [45-48].

In the view of the present inventors, the addition of any other material must be carefully considered in view of the possibility of adversely affecting the chemistry of the superconducting phase and thereby affecting the likely superconducting performance of the material. Furthermore, the addition specifically of high melting point materials (higher melting point compared to (RE)BCO) must be carefully considered since otherwise there can be a severe effect on the ability to provide single grain formation, due to the creation of unwanted sub-grain nucleations.

The present invention is based on the inventors' insight that fibre reinforcement may be used to enhance the mechanical strength of (RE)BCO materials without deleteriously affecting the superconducting properties of such materials.

The present invention has been devised in light of the above considerations.

Accordingly, in a first preferred aspect, the present invention provides a bulk superconductor device comprising a single grain RE-BCO element incorporating reinforcing fibres.

In a second aspect, the present invention provides a method of manufacturing a bulk superconductor device, the method comprising:
providing a precursor powder;
providing reinforcing fibres;
forming a precursor body from the precursor powder and the reinforcing fibres; and
subjecting the precursor body to melt processing to form a single grain RE-BCO element incorporating the reinforcing fibres.

As will be discussed in further detail below, the preferred embodiments of the invention allow successful reinforcement of (RE)BCO materials (including (RE)BCO—Ag materials) with fibres which can significantly improve the mechanical strength of these ceramic materials while maintaining the superconducting properties. For this purpose, the fibres can be distributed randomly in the bulk in order to enhance the tensile strength of the bulk isotropically.

The first and/or second aspect of the invention may have any one or, to the extent that they are compatible, any combination of the following optional features.

The term “single grain” as used in the present disclosure is widely used in the technical literature. It refers to the superconductor element having a matrix phase having an aligned crystalline orientation extending across substantially the whole element without the intervention of grain boundaries between different parts of the matrix phase. However, it is permitted for there to be heterogeneous boundaries in the superconductor element, to allow the incorporation of precipitates, other non-superconducting phases, reinforcing fibres (in the present disclosure) and also to allow the presence of at least some defects in the superconductor element.

In one preferred embodiment, the rare earth barium copper oxide is an yttrium barium copper oxide (YBCO, such as YBa₂Cu₃O_{7-δ} but may be Y₂Ba₄Cu₇O₁₄₋ₓ or YBa₂Cu₄O₈), erbium barium copper oxide, samarium barium copper oxide, neodymium barium copper oxide, europium barium copper oxide, gadolinium barium copper oxide, ytterbium barium copper oxide, or mixed rare-earth superconductors including (Y,Gd)BCO, (Y,Sm)BCO, (Nd,Sm)BCO, (Nd,Eu,Gd)BCO, (Nd,Sm,Gd)BCO and further suitable combinations as will be apparent to the skilled person.

Preferably, the superconductor element is a superconductor at a temperature of T_{c}(˜92/93 K) or below, at least in zero or substantially zero applied magnetic field.

The single grain (RE)BCO element may comprise RE-211 pinning sites distributed in a RE-123 matrix. It is therefore understood that the expression “single grain” does not necessarily require a “single crystal” structure, given that there may be phase boundaries within the single grain. Such pinning sites enhance the superconducting properties of the material via magnetic flux pinning, in magnetic fields (including self-field).

The single grain (RE)BCO element may further comprise Ag. Preferably, the element comprises at least 1 wt. % Ag, more preferably at least 2 wt. % Ag, more preferably at least 3 wt. % Ag, more preferably at least 4 wt. % Ag, more preferably at least 5 wt. % Ag. The incorporation of Ag can improve the mechanical strength against fracture, without significant deleterious effect on superconducting properties. Preferably, the element comprises not more than 20 wt. % Ag.

The single grain RE-BCO element may further comprise a grain refining agent. The grain refining agent may be selected for example from Pt or CeO₂.

The reinforcing fibres may comprise a ceramic. The reinforcing fibres may comprise a refractory metal. The reinforcing fibres may be composite or hybrid fibres comprising a ceramic and a refractory metal. In some embodiments, the reinforcing fibres may comprise a refractory metal core and a ceramic cladding surrounding the core. For example, the ceramic may be SiC. For example, the refractory metal may be W. The present inventors consider that such embodiments are advantageous because the SiC, being the clad of the fibre, integrated well with the matrix and the W core retained its properties and contributed a significant enhancement of the mechanical strength of the reinforced bulk element.

The element may have a minimum dimension of at least 5 mm. This dimension may be at least 10 mm or at least 15 mm.

The element may have a maximum dimension of at least 10 mm. This dimension may be at least 20 mm, at least 30 mm, at least 40 mm or at least 50 mm.

The element may have a volume of at least 1000 mm³. The element may more preferably have a volume of at least 1500 mm³, at least 2000 mm³, at least 5000 mm³, or at least 10000 mm³.

The reinforcing fibres have a length of at least 1 mm, more preferably at least 5 mm. Such a length limitation may apply to the reinforcing fibres on average. Alternatively, such a length limitation may apply to all of the reinforcing fibres in the element.

The bulk superconductor device may further comprise external reinforcement. Such external reinforcement may be selected from one or more of:

resin and/or fibre reinforced resin reinforcement;

metallic jacket reinforcement; and

shrink-fit reinforcement.

The melt processing may be a top seeded melt growth (TSMG) process. The precursor powder may comprise a mixture of RE-123 and RE-211.

The melt processing may be a top seeded infiltration growth (TSIG) process in which the precursor body is disposed on a liquid source precursor. The precursor powder may comprise RE-211.

The present inventors have confirmed experimentally that embodiments of the invention work using the TSMG process and using the TSIG process. In the TSIG process the reinforcing fibres are incorporated in the precursor body.

A buffer pellet may be disposed between a seed crystal and the precursor body during melt processing. The inventors consider that there are three primary advantages possible due to the employment of a buffer pellet. Firstly, the seed crystal is shielded from the liquid phase component, thereby increasing the reliability of single grain growth. Secondly, it is possible to reduce or prevent cracks/unwanted defects arising from lattice-mismatch effects (Seed-Sample) from penetrating into the main (RE)BCO material. Thirdly, the buffer pellet may reduce or prevent diffusion of a seed crystal element (e.g. Nd/Sm) into main (RE)BCO element.

The invention includes the combination of the aspects and optional features described except where such a combination is clearly impermissible or expressly avoided.

Further optional features of the invention are set out below.

As will be understood, the manufacture of high temperature superconductor (HTS) materials such as RE-BCO typically requires a complex production process, with multiple calcinations of precursor materials ingredients at high temperatures (e.g. ranging from 800° C. to 950° C.) for several hours followed by sintering or melt processing. Furthermore, HTS materials require heat treatment (e.g. at about 400-850° C.) in an oxygen-containing atmosphere, optionally with associated controlled cooling, in order to control the required oxygen stoichiometry for the desired superconducting properties.

The complex role of oxygen in the manufacturing process prohibits the use of many reinforcing materials. This is because nearly all potential reinforcing materials that are suitably stable at the processing temperatures (e.g. many metals, carbon, etc.) will react/oxidize during the manufacturing process and interfere with formation of the required HTS material. Such reaction/oxidation may either create impurities or deplete oxygen at a critical time in the production process. Each of these effects can deleteriously affect the development of the required HTS properties.

Some attempts to develop useful HTS materials focus on external reinforcement such as packing-in-tube (PIT) wire production, encasing HTS in steel, or additive processes such as attempting to apply HTS as a coating on tape substrates. Both PIT and external encasing are difficult to produce economically in shapes and constructions for practical applications. Techniques which attempt to grow HTS on reinforcement substrates are experimental and, to date, far from producing significantly large HTS components for practical applications.

Attempts have been made to internally reinforce HTS using discontinuous metal fibers (Cu, Ag, Au, etc.) and particles. These have generally failed due to a) contamination during production and/or b) agglomeration of the discontinuous particles/fibres during the melt phase of production. The agglomeration can produce crack and fault planes which reduces the strength of, or even causes disintegration of, the final HTS element.

In the preferred embodiments of the present invention, reinforcing fibre comprising SiC is used. Such fibre may be long fibres or even continuous fibre. This is used for physical internal reinforcement of a HTS material to prevent cracking and contamination, which can otherwise cause the HTS material to fail. The SiC fiber with its high-aspect ratio is distributed through the pre-sintering powder then processed with the HTS sample through its normal sintering cycle.

The insight of the present inventors is that carbon fibre can be a strong reinforcing material which is stable over the wide range of temperatures involved in processing and sintering bulk HTS. However, carbon is highly reactive with oxygen which prohibits the use of most carbon fiber for internal HTS reinforcement. SiC fibre creates a durable layer of silicon dioxide SiO₂ from the reaction of the silicon with oxygen. This SiO₂ layer prohibits further reaction with oxygen during the remaining HTS production process. The use of continuous and/or long fiber SiC prevents the agglomeration of discontinuous fibers/particles which weakens and disintegrates the HTS crystal.

Other aspects and embodiments of the invention provide the aspects and embodiments described above with the term “comprising” replaced by the term “consisting of” and the aspects and embodiments described above with the term “comprising” replaced by the term “consisting essentially of”.

“and/or” where used herein is to be taken as specific disclosure of each of the two specified features or components with or without the other. For example “A and/or B” is to be taken as specific disclosure of each of (i) A, (ii) B and (iii) A and B, just as if each is set out individually herein.

### SUMMARY OF THE FIGURES

Embodiments and experiments illustrating the principles of the invention will now be discussed with reference to the accompanying figures in which:

FIG. 1 shows the trapped field profile measured at 77 K in a YBCO sample which cracked in an earlier experiment where it was exposed to very large magnetic field of 18 T. Cracking was not evident to the normal eye after the magnetization process however, when measured for trapped field clearly showed the presence of two grains with net reduced trapping ability. Arrows and artificial white space are added to the view in order to indicate regions of high trapped field with respect to the scale.

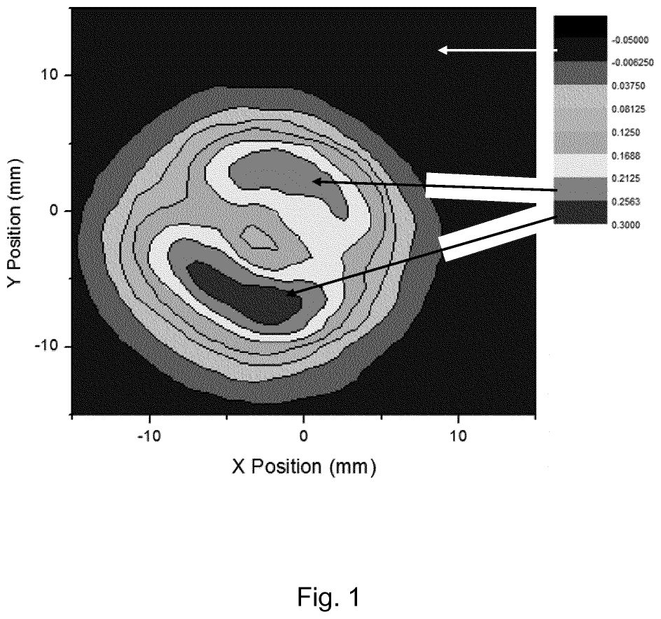

FIG. 2(a) is a schematic drawing showing the application of compressive force parallel to growth sector direction. FIG. 2(b) shows a view of an YBCO sample being tested for mechanical tensile strength employing the “Brazilian technique”. The crack formed in the sample during fracture point is shown in FIG. 2(c).

FIGS. 3(a)-(c) show scanning electron micrographs obtained from: FIG. 3(a) W-metallic fibre; FIG. 3(b) multi-filamentary SiC fibre; and FIG. 3(c) cross-section of the monofilament SiC fibre with W-core

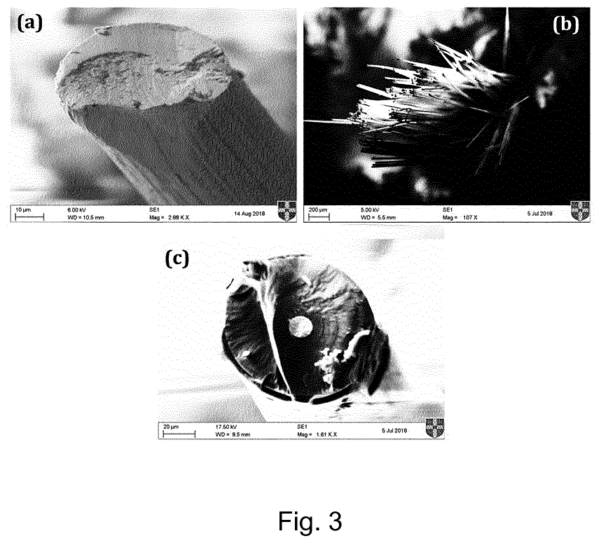

FIGS. 4(a) and 4(b) show the results of thermal scans obtained from the precursor powder 75 wt. % Y-123+25 wt. % Y-211+0.5 wt. % CeO₂, with and without W-fibres. In the original colour version of these graphs, the curves in red and black colours correspond to the configuration: with and without fibres respectively. FIG. 4(b) shows a magnified version of the region of the scan indicated in FIG. 4(a), showing that the difference in peritectic temperature is only by 1° C. In FIG. 4(b), corresponding to the high temperature region of FIG. 4(a), the upper loop corresponds to the configuration with fibres.

FIGS. 5(a) and 5(b) show trapped field measured at 77 K in: FIG. 5(a) Reference sample, YBCO; and FIG. 5(b) YBCO with W-fibres.

FIGS. 6(a)-(c) show scanning electron micrographs recorded under different magnifications in the YBCO sample containing W-fibres revealing the formation and presence of Y-2411 phase.

FIG. 7 shows the tensile strength, as assessed employing the Brazilian technique, on YBCO samples with and without W-fibres. It can be seen that the addition of W-fibres reduced the mechanical strength of the YBCO single grains.

FIG. 8 shows TG-DTA scans obtained in YBCO precursor powder with and without 0.25 wt % SiC fibres. The peritectic temperature was lowered by 3° C. compared to the standard powder.

FIGS. 9(a) and 9(b) show trapped field measured at 77 K in YBCO sample (of 16 mm in diameter) containing dispersed multi-filamentary SiC fibres. The 3-D trapped field profile is shown in FIG. 9(a) and the 2-D contour is shown in FIG. 9(b). The white arrows indicate the regions of the plot corresponding to the values on the scale.

FIG. 10 shows the tensile strength, measured employing the Brazilian technique, in YBCO samples with and without dispersed SiC fibres (of 1.5 micron in diameter) in YBCO. Samples were fabricated employing BA-TSMG technique.

FIG. 11 shows the positioning of three stacked multifilament SiC fibres at the center of a preform compact.

FIGS. 12(a)-(c) show trapped field measured at 77 K in YBCO samples containing stacks of SiC fibres at the center of the preform compact.

FIG. 13(a) shows the placement of three mono-filament SiC fibres directly on the precursor powder present in the steel die, at the center of the preform compact. FIG. 13(b) shows a schematic of three mono-filament SiC fibres located in the centre of a single grain sample, with the mono-filament SiC fibres shown in cross section.

FIG. 14 shows the tensile strength as measured in the YBCO samples with and with mono-filament hybrid SiC fibres containing W-core

FIG. 15 shows an SEM cross-section of the YBCO sample containing mono-filament SiC fibres. The micrograph shows that the fibres have good adherence in the YBCO matrix and has not affected the single grain growth process.

### DETAILED DESCRIPTION OF THE INVENTION

Aspects and embodiments of the present invention will now be discussed with reference to the accompanying figures. Further aspects and embodiments will be apparent to those skilled in the art. All documents mentioned in this text are incorporated herein by reference.

Rare-earth based high temperature ‘(RE)BCO’ superconductors have been well known not only for their fascinating properties (like zero resistance and perfect diamagnetism, below certain critical parameters) but also for the potential to be used in several real scale engineering and technological applications such as trapped field magnets, rotating electrical machines, magnetic bearings and flywheel energy storage systems. (RE)BCO ceramic superconducting materials have been well researched for the last 30 years and potential fabrication methodologies have been developed to grow single grains out of these materials which, with engineered microstructures for enhanced flux pinning, then enable the trapping of large magnetic fields as required for practical applications out of these materials. Due to the extensive work carried out on these materials, the superconducting properties such as current carrying ability (J_{c}) and their field dependence J_{c}(H), associated irreversibility fields (Hᵢᵣᵣ) have been tuned and enhanced to satisfactory levels via tuning of processing parameters and addition of suitable dopants/additives for enhanced flux pinning strength. However, their mechanical properties remain weak due to their inherent ceramic nature capped further with varieties of defects such as porosity, cracks, lattice mismatch associated stacking fault defects and more. Very often, these materials when exposed to large magnetic fields end up cracking due to enormous tensile forces that are generated due to Lorentz forces. In the present work, the inventors now disclose a powerful reinforcement methodology. In some examples of the implementation of the invention, hybrid SiC fibres containing W-core are used as reinforcing fibres, which improve the mechanical properties of these materials significantly while retaining their superconducting properties.

By the present disclosure, it is shown that fibres can enhance the internal mechanical strength of (RE)BCO materials. The intent of fibre introduction in bulk superconductors is primarily to provide additional mechanical strength by forming a composite structure, and to prevent crack growth and propagation. The mechanical strength enhancement to be achieved in bulk superconductors must be significant while simultaneously overcoming any negative effects on the current carrying capabilities of the sample. It is of interest to consider the effectiveness of the integration of the fibres into the bulk material and the manner in which the fibres are bonded to the matrix within the material.

Experimental

Different sets of YBCO single grain bulks of 16 mm, 20 mm and 25 mm in diameter were fabricated with added fibres employing the top seeded melt growth (TSMG) technique. The fibres studied in the present work are of three types: (i) metallic tungsten fibre, (ii) SiC fibres and (iii) hybrid fibres containing SiC as clad and tungsten as core. In order to prepare the single grain YBCO samples, precursor powder comprising of 75 wt. % Y-123+25 wt. % Y-211+0.5 wt. % CeO₂ was used. Y-123 and Y-211 powders each of 99.9% purity were procured from Toshima Manufacturing Co. Ltd., Japan and CeO₂ of 99.9% purity purchased from Sigma Aldrich were used. All the fibres studied in the present work were procured from American elements, Los Angeles, USA and were introduced into precursor powder during the compaction stage either in the mixed form or in the configurations as will be discussed in Section 3. For a fair comparison, test samples with no added fibres were also prepared in each of the sets, under similar conditions.

The influence of the added fibres on the peritectic temperature of the mixed precursor powder (comprising 75 wt % Y-123+25 wt % Y-211+0.5 wt % CeO₂+fibres) was studied by subjecting the powder samples to thermal scans, employing Thermogravimetry/Differential thermal analysis (TG-DTA), to temperatures of 1200° C. with heating and cooling rates of 10° C. per minute. For single grain fabrication, the pressed pellets were capped with a 5 mm diameter buffer pellet comprising 75 wt. % Y-123+25 wt. % Y-211 and then a NdBCO or generic seed crystal [49, 50] was placed on the top of the buffer pellet. The entire assembly was then melt processed following a standard heat profile disclosed elsewhere [51]. Typically, the heat treatment comprised heating the sample assembly in a box furnace to a temperature of 1055° C. (a temperature above the Tₚ of Y-123 phase to promote the incongruent melting of Y-123 phase to form solid Y-211 and copper-rich liquid phase BaCuO₂ and CuO). The sample assembly was then slowly cooled at the rate of 0.5-0.7° C./h through the Tₚ of the compound to 980° C. and then furnace cooled. This heat treatment enabled single grain growth formation. The samples thus grown were subsequently oxygenated in a tube furnace maintained at a temperature of 450° C. with and oxygen gas flow rate of 100 ml/min. The oxygenation process was carried out for 150 hours to completely transform the tetragonal, non-superconducting Y-123 phase to the orthorhombic, superconducting phase.

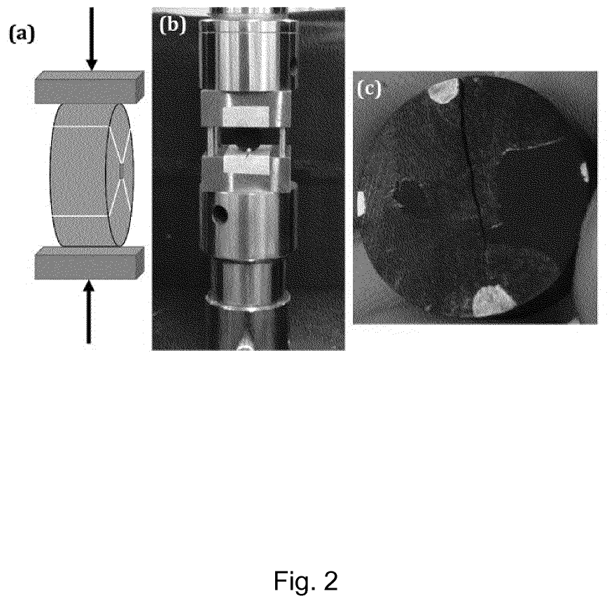

In order to measure the trapped field ability of the samples, each of them was field cooled to liquid nitrogen temperature (77 K) in an electromagnet (with applied field of 1.4 T). The applied external field was then removed and then the trapped field in the sample was measured employing a purpose built 3D rotating Hall sensor facility. More details of the trapped field measurement facility and methodology followed can be found elsewhere [52]. The mechanical tensile strength of the YBCO bulk superconductors with and without fibres was measured by the Brazilian technique [53-55]. For each of the samples, the circumferential surface of the oxygenated samples were polished in order to remove any irregularities. The samples were then subjected to a mechanical test by applying a compressive force parallel to the growth sector directions, as shown in FIG. 2(a), in a tensile testing machine (Instron, model 5584) until a hairline crack formed (as shown in FIG. 2(c)) along the principal axis due to induced tensile stress in the perpendicular direction to that of the applied force [53-55].

The indirect tensile strength ‘σ’ was then computed following:

$$σ = \frac{2 P}{π dt}$$

Here, P is the applied load on sample when it fractures, and d and t are the diameter and thickness of the sample respectively. Samples were sliced using a diamond saw and polished down to micron-level finish, using grinding foils and colloidal suspensions containing diamond particles. The microstructure of the fractured or polished samples at every stage was observed using either a scanning electron microscope (with EDX facility) or an optical microscope equipped with polarizer. The composition of the fibre was analysed with EDX spectrometer installed on the scanning electron microscope.

Results and Discussion

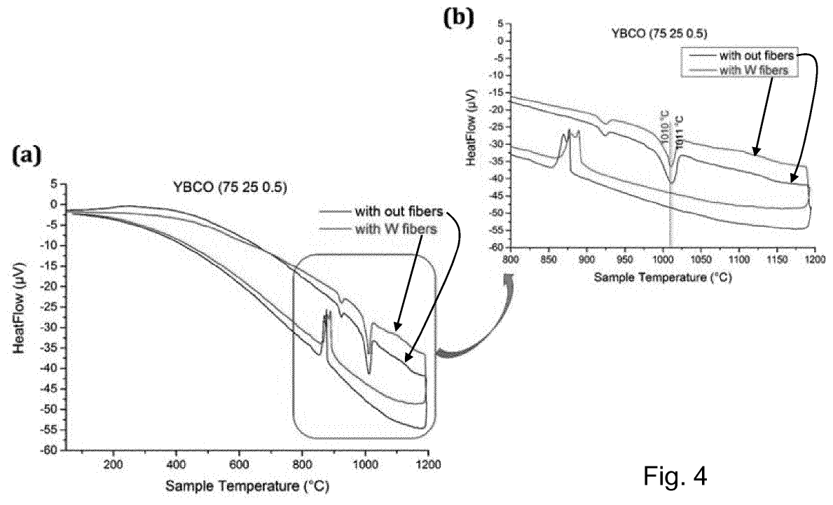

FIG. 4 shows electron micrographs of the fibres employed in the present work i.e. W-metallic fibre, multi-filamentary SiC fibre and monofilament SiC fibre with W-core. The micrographs also show their cross-sections. It can be seen that the monofilament SiC fibre is about 100 μm in diameter with a tungsten core of about 15 μm diameter. The presence of these phases was confirmed with EDX analysis carried out on the fibers. More details about the fibres can be found in Table-1.

TABLE 1
Details of various fibres used in the present work

| | Diameter | Supplier and | Melting | |
|---|---|---|---|---|
| Fibre-type | (μm) | code | point | Remarks |
| W-metallic | 50 | American | 3410° C. | Tensile |
| fibre | | elements | | strength: |
| | | W-M-02-W | | 750 MPa |
| Multi- | 1.5 | American | 2730° C. | Stack of 500 |
| filamentary | | elements | | fibres |
| SiC fibre | | SI-C-01-FIB | | |
| Mono- | 100 | American | Not | Core - W and |
| filament | | elements | provided | Clad is SiC |
| SiC fibre | | SI-C-01-MFIL | | |

YBCO single grained bulks with and without fibres in each of the sets were fabricated following the BA-TSMG technique. Details from each of these sample sets are provided in the following sections of this disclosure. It can be seen from these sections that in spite of the presence of fibres (which have higher melting point compared to the processing temperature), it remained possible to grow the samples into single grains.

W-Fibre Added YBCO

W-metallic fibres of 50 micron in diameter, were chopped into lengths of 1-6 mm and mixed with YBCO precursor powder containing 75 wt. % Y-123+25 wt. % Y-211+0.5 wt. % CeO₂, using an agate mortar and pestle for 1 hour. This mixed powder was subsequently pre-sintered at 900° C. for 2 hours. The powder with and without added W-fibres were subjected to thermal scans employing TG-DTA. The results are shown in FIG. 4. FIG. 4 confirms that the addition of W-fibres does not influence the peritectic temperature Tₚ of the powder (with reduction of Tₚ by only 1° C. compared to the standard composition).

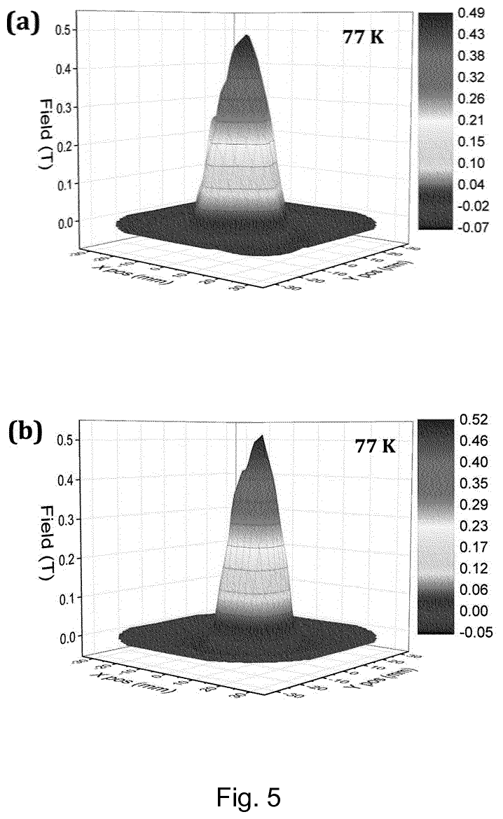

The sintered powder containing W-fibers was compacted into pellets of 25 mm in diameter, in a steel die and supported with a NdBCO seed crystal and then subjected to BA-TSMG process which enabled them to grow into single grains. Single grained samples were thus obtained after the heat treatment and were subsequently oxygenated. They were subjected to testing in order to measure both their superconducting and mechanical properties. Trapped field measured in both the samples (YBCO with and without W-fibres) at 77 K are shown in FIG. 5. It can be seen that the trapped field ability of the sample was mildly enhanced due to the addition of W-fibre.

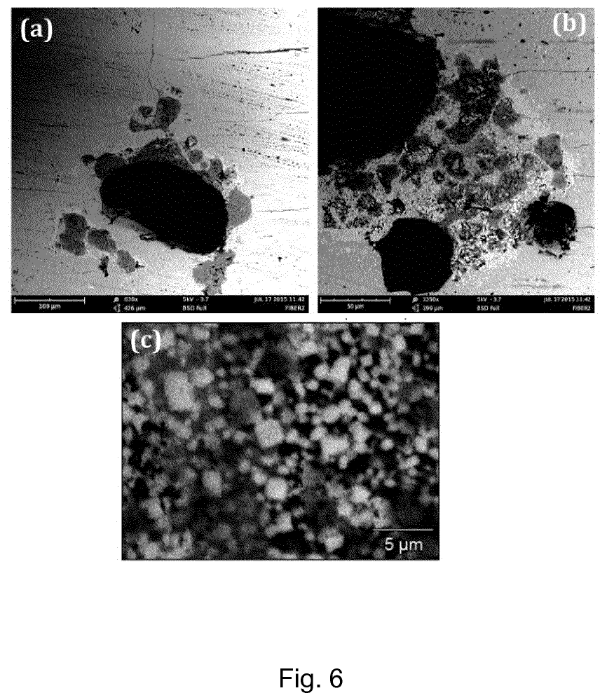

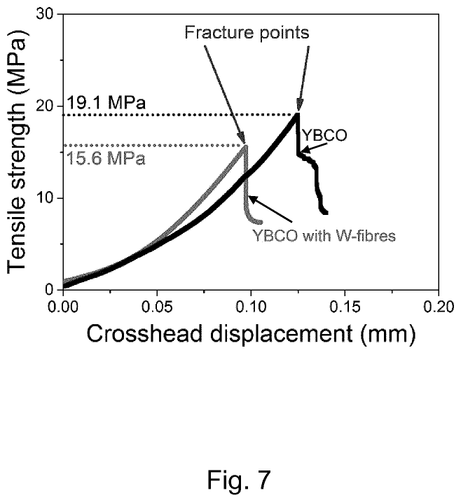

YBCO samples containing W-fibre when polished and further examined under scanning electron microscope (FIG. 6) revealed the formation and presence of Y₂Ba₄Cu₁W₁O_{y} (Y-2411) phase, whose presence is known to enhance the flux pinning strength of the material thereby increasing the superconducting properties like trapped field and field dependence of J_{c} [56, 57]. Though the superconducting properties have shown improvement with the addition of W-fibres, the mechanical properties deteriorated as can be seen from FIG. 7.

Without wishing to be bound by theory, the present inventors propose that the reason for the deterioration of mechanical properties is likely to be due to the fact that the W-fibers have reacted completely with the aggressive liquid phase (comprising BaCuO₂ and CuO) forming Y-2411 phase. The intention for adding fibres into (RE)BCO i.e. for improvement of mechanical strength was therefore not satisfied by the addition of W-fibres. This motivated the inventors to use alternative fibers that may have better phase stability with the aggressive liquid phase. The inventors therefore proposed to use a fibre such as SiC fibre. The employment of such fibres in (RE)BCO is discussed in the subsequent sections of this disclosure.

Multi-Filamentary SiC-Fibres Added YBCO

A stack of 500 multi-filamentary SiC fibres, each of the fibres being 1.5 μm in dimeter were chosen to introduce into YBCO in two different configurations:
(i) Slice and mix the fibres with the YBCO precursor powder followed with subsequent calcination at 900 C for 2 h similar to that followed with W-fibers (as discussed above) and fabricating the samples employing this powder via BA-TSMG technique.
(ii) To introduce the fibres of required lengths as stacks at the centre of the preform compact.

Configuration (i)

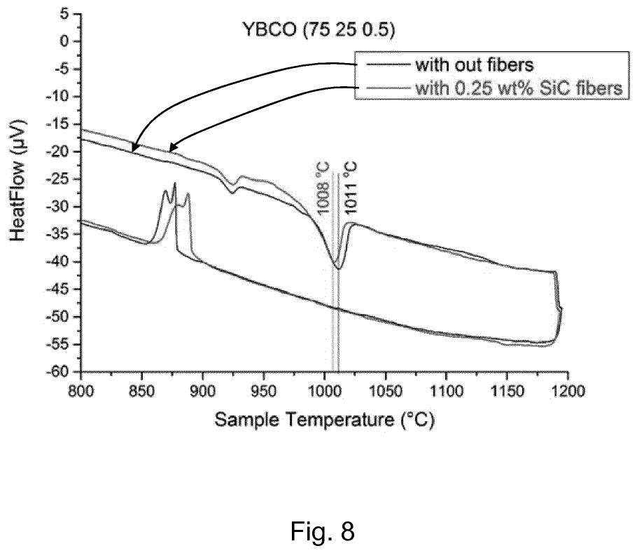

For the first configuration, the multi-filamentary SiC fibers were chopped into lengths of 1-4 mm and were mixed with YBCO precursor powder such that the composition resulted as 75 wt. % Y-123+25 wt. % Y-211+0.5% CeO₂+X wt. % SiC fibre (X=0, 0.25, 0.5 and 1) and subsequently pre-sintered at 900° C. for 2 hours, followed by through mixing in agate mortar and pestle for 1 hour. DTA scans measured in the YBCO precursor powder with and without 0.25 wt. % SiC fibres are shown in FIG. 8.

The mixed YBCO powder containing dispersed multi-filaments of SiC-fibres was compacted into a pellet and capped with a buffer pellet and further with an NdBCO seed crystal. The entire sample assembly was then heat treated in a box furnace employing the Buffer-assisted TSMG technique. The sample of about 20 mm in diameter grew into single grain.

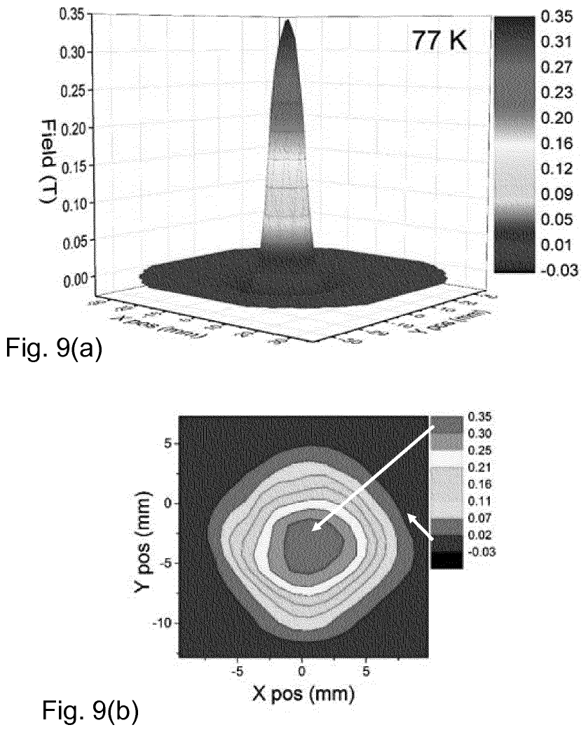

Trapped field (both 3-D profile and 2-D contour map) measured in the YBCO samples containing 0.25 wt % SiC fibres are shown in FIGS. 9(a) and 9(b) respectively. It can be seen from these figures that the sample, in spite of containing SiC fibres (with high melting point), successfully grew into single grains as evidenced by clear 4-fold facet lines confirmed visually on the external surface of the samples and further confirmed from the single peak from trapped field measurements (see FIGS. 9(a) and 9(b)). This value of trapped field is smaller when compared to YBCO samples with no added SiC fibres.

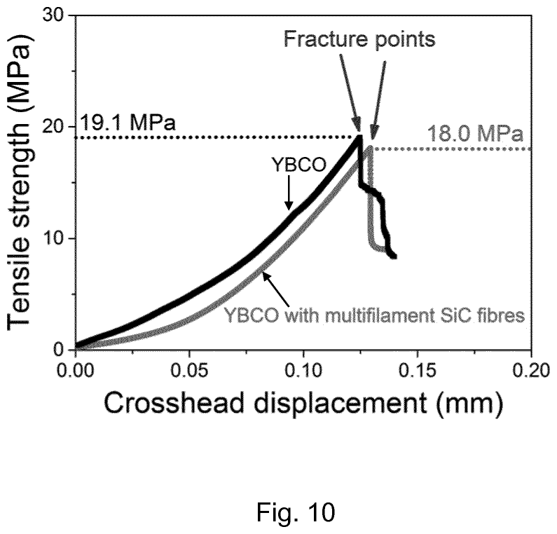

Mechanical tensile strength measured in the SiC fibre-reinforced YBCO samples is shown in FIG. 10. It can be seen that the addition and dispersion of SiC fibres in the precursor powder has improved the mechanical strength of reinforced single grained YBCO when compared to a similar situation where the reinforcement was performed in YBCO with W-fibres (see FIG. 7).

Configuration (ii)

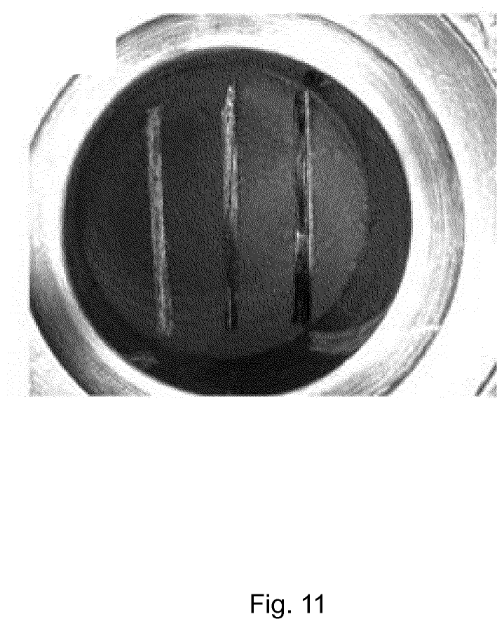

For the second configuration, the multi-filament SiC fiber stack was chopped to lengths of about 20 mm and placed at the center of the preform compact as shown in FIG. 11. In spite of the presence of thick stacks of SiC fibers at the center of the preforms, the samples still grew into single grains. However, it was noted that there was the appearance of macro-cracks at the sides of the samples in this configuration.

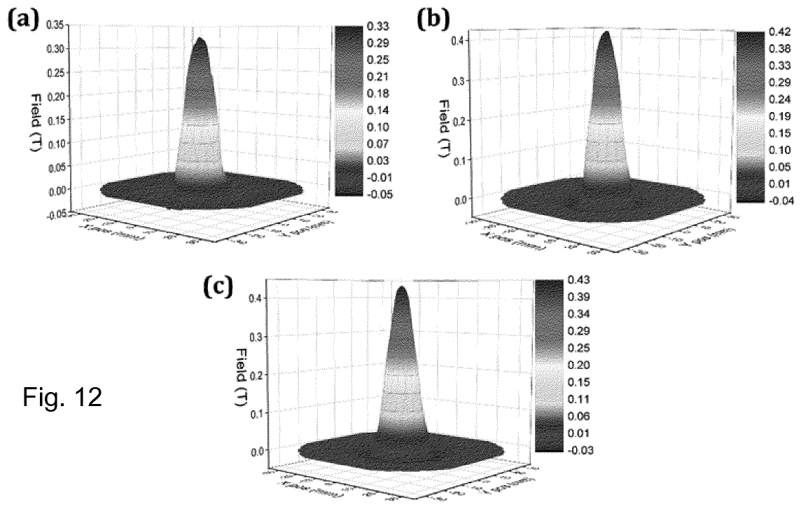

Trapped field measured in these samples at 77 K are shown in FIGS. 12(a), 12(b) and 12(c).

Mono-Filamentary Hybrid SiC Fibre Added YBCO

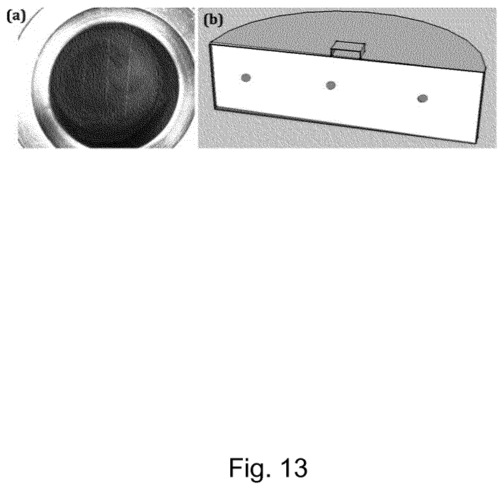

A composite fibre with W-core of diameter about 15 μm encapsulated in SiC cladding accounting to 100 μm diameter was examined for reinforcement of (RE)BCO. Three of these mono-filamentary SiC fibres were arranged at the center of the preform compact as shown in FIG. 13(a). The resultant position of the mono-filamentary SiC fibres in the fully-assembled preform compact is shown in FIG. 13(b), in which a schematic cross sectional view is taken through the preform compact in a direction perpendicular to the direction of the mono-filamentary SiC fibres.

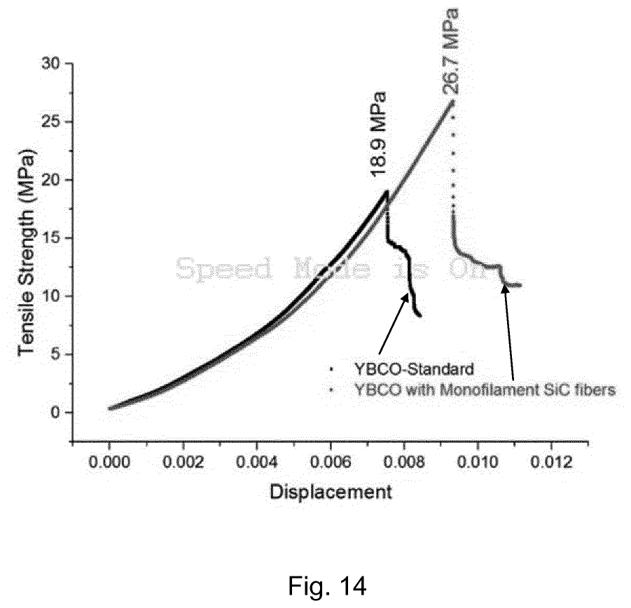

Samples containing these composite fibres successfully grew into single grains. Unlike the samples reported above for configuration (ii), no major macro-cracks were formed at the side walls of the samples. These samples were oxygenated and subsequently machined for measuring the tensile strength employing the Brazilian technique. Results of the tensile strength property along with that measured in standard YBCO sample can be seen in FIG. 14.

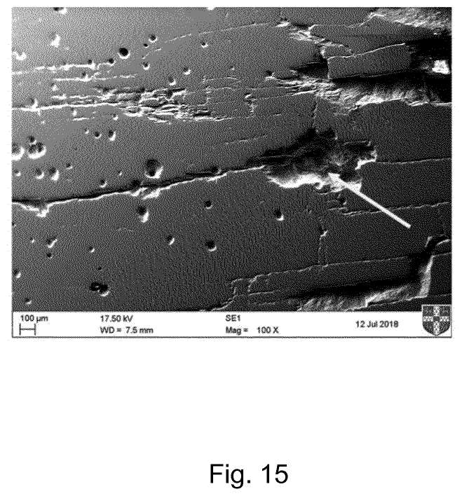

The sample after mechanical tests was polished and the cross-section was observed under a scanning electron microscope. This study revealed good adherence of the fibre with the YBCO matrix as can be seen from FIG. 15 and further has not caused any sub-grain formation/additional nucleation. This is considered to be particularly relevant for retaining the superconducting properties of the single grain superconducting element.

The fact that the incorporated fibres have not created sub-grains, even in the local regions, is considered by the inventors to be impressive from the aspects of crystal growth and macro-superconducting properties. Thus it can be seen that the YBCO samples reinforced with composite SiC fibres not only retained the superconducting properties but improved the internal mechanical strength of bulk YBCO ceramics. This makes such devices suitable for many applications of the type discussed above.

The approach of providing internal reinforcement as discussed above does not rule out the advantages of providing additional external reinforcement, such as resin impregnation and/or shrink-fitting inside a reinforcing shell (e.g. of stainless steel) as discussed above. Such complementary reinforcement techniques make the device suitable for challenging applications such as motors and bearings where these products can be subjected to large rpm (rotations per minute).

Batch Processing of Fibre Reinforced YBCO—Check for Reproducibility/Repeatability

Several YBCO and GdBCO samples of different dimensions in the range 16 mm to 32 mm were successfully reinforced with the composite SiC fibres reported above. The samples were grown employing the top seeded melt growth and top seeded infiltration growth techniques. This work confirms the reproducible and repeatable nature of the reinforcement and its compatibility with the top seeded melt growth technique for forming single grain devices.

### CONCLUSIONS

Rare-earth based high temperature superconductors have significant potential in a range of engineering and technological applications, including but not limited to, compact electric motors, friction-free self-stabilizing bearings for energy storage fly wheels and trapped field magnets. These materials in single grain form are of great interest due to the fact that they can trap magnetic fields that are almost ten times greater than similar-sized permanent magnets. Considerable work has already been devoted by various researchers to improve the superconducting properties through introduction of selective additivities/dopants/defects which improved the flux pinning strength of these composites. However, in general, the mechanical properties of these superconducting ceramics have been poor and hence have been of serious concern with respect to their practical applications. In particular, when these materials are exposed to large magnetic fields, the magnetic stresses generated (proportional to B²), can very easily fracture the materials by cracking them and forming two or more grains resulting in greatly reduced ability for them to trap magnetic field. In this context, a few efforts have been made in literature to externally reinforce the bulk superconductors by wrapping them in carbon fiber followed by complex resin impregnation, optionally further fitting the devices with steel tubes. For some applications, this is not practical from the point of view of efficient industrial production. Additionally, shrink-fitting has been employed to pre-stress the bulk superconductors in order to improve their mechanical strength.

In the present work, we have examined a relatively simple reinforcing methodology that enables internal reinforcement improving the tensile strength of the bulk (RE)BCO ceramics. Reinforcing fibres are mixed with the precursor powder. A pressed powder and fibre compact is then subjected to melt growth techniques to obtain single grains. Three different varieties of fibres were tested in the present work (a) W-metallic fibres, (b) SiC fibres and (c) composite SiC fibres containing W in its core. The single grained (RE)BCO bulks reinforced with the composite SiC fibres showed enhancement both in the superconducting and mechanical properties in comparison to the standard (RE)BCO ceramics. The combination of properties achieved by employing SiC and tungsten as reinforcing agents is found to enable better phase stability with the material while retaining the properties of tungsten since SiC has successfully shielded W from reaction with the aggressive liquid phase. Without wishing to be bound by theory, the inventors consider that this is the reason for the enhanced internal mechanical strength in these reinforced ceramic composites. These materials when further subjected to external reinforcement such as by using with stainless steel rings via shrink-fit technique can deliver robust products as required for real-scale applications.

The features disclosed in the foregoing description, or in the following claims, or in the accompanying drawings, expressed in their specific forms or in terms of a means for performing the disclosed function, or a method or process for obtaining the disclosed results, as appropriate, may, separately, or in any combination of such features, be utilised for realising the invention in diverse forms thereof.

While the invention has been described in conjunction with the exemplary embodiments described above, many equivalent modifications and variations will be apparent to those skilled in the art when given this disclosure. Accordingly, the exemplary embodiments of the invention set forth above are considered to be illustrative and not limiting. Various changes to the described embodiments may be made without departing from the spirit and scope of the invention.

For the avoidance of any doubt, any theoretical explanations provided herein are provided for the purposes of improving the understanding of a reader. The inventors do not wish to be bound by any of these theoretical explanations.

Any section headings used herein are for organizational purposes only and are not to be construed as limiting the subject matter described.

Throughout this specification, including the claims which follow, unless the context requires otherwise, the word “comprise” and “include”, and variations such as “comprises”, “comprising”, and “including” will be understood to imply the inclusion of a stated integer or step or group of integers or steps but not the exclusion of any other integer or step or group of integers or steps.

It must be noted that, as used in the specification and the appended claims, the singular forms “a,” “an,” and “the” include plural referents unless the context clearly dictates otherwise. Ranges may be expressed herein as from “about” one particular value, and/or to “about” another particular value. When such a range is expressed, another embodiment includes from the one particular value and/or to the other particular value. Similarly, when values are expressed as approximations, by the use of the antecedent “about,” it will be understood that the particular value forms another embodiment. The term “about” in relation to a numerical value is optional and means for example +/−10%.

### REFERENCES

A number of publications are cited above in order to more fully describe and disclose the invention and the state of the art to which the invention pertains. Full citations for these references are provided below. The entirety of each of these references is incorporated herein.
1. D. Cardwell, Processing and properties of large grain (RE)BCO, Mater. Sci. Eng. B 53 (1998) 1-10.
2. Durrell, J. H., Dennis, A. R., Jaroszynski, J., Ainslie, M. D., Palmer, K. G. B., Shi, Y.-H., Cardwell, D. A. (2014). A trapped field of 17.6 T in melt-processed, bulk Gd—Ba—Cu—O reinforced with shrink-fit steel. Superconductor Science and Technology, 27(8), 082001. http://doi.org/10.1088/0953-2048/27/8/082001
3. A. M. Campbell, D. A. Cardwell, Bulk high temperature superconductors for magnet applications, Cryogenics 37 (1997) 567.
4. M. Murakami, Novel application of high Tc bulk superconductors, Appl. Supercond. 1 (1993) 1157-1173.
5. D. K. Namburi, Y. Shi, K. G. Palmer, A. R. Dennis, J. H. Durrell, D. A. Cardwell, Control of Y-211 content in bulk YBCO superconductors fabricated by a buffer-aided, top seeded infiltration and growth melt process, Supercond. Sci. Technol. 29 (2016) 034007.
6. R. Cloots, T. Koutzarova, J-P Mathieu, M. Ausloos, From RE-211 to RE-123. How to control the final microstructure of superconducting single-domains, Supercond. Sci. Technol. 18 (2005) R9-R23.
7. Devendra Kumar, N., Shi, Y., & Cardwell, D. A. (2016) Chapter-1, Fabrication of bulk (RE)BCO superconductors by the Infiltration and Growth process: Past, Present And Future, p 1-35, Superconductivity: Applications Today and Tomorrow. (M. Muralidhar, Ed.). Nova Science Publishers. ISBN: 978-1-63483-756-9.
8. D A Cardwell and N Hari Babu, Improved magnetic flux pinning in bulk (RE)BCO superconductors, AIP Conference Proceedings 986, 543 (2008); doi: 10.1063/1.2900395
9. N. Hari Babu, E. S. Reddy, D. A. Cardwell, and A. M. Campbell, Artificial flux pinning centers in large, single-grain (RE)-Ba—Cu—O superconductors, Appl. Phys. Lett. 83, 4806 (2003); https://doi.org/10.1063/1.1631738.
10. Jin, S., Tiefel, T. H., Sherwood, R. C., van Dover, R. B., Davis, M. E., Kammlott, G. W., & Fastnacht, R. A. (1988). Melt-textured growth of polycrystalline YBa2Cu3O7-δ with high transport Jc at 77 K. Physical Review B, 37(13), 7850-7853. http://doi.org/10.1103/PhysRevB.37.7850
11. Nariki, S., Sakai, N., & Murakami, M. (2005). Melt-processed Gd—Ba—Cu—O superconductor with trapped field of 3 Tat 77 K. Superconductor Science and Technology, 18(2), S126-S130. http://doi.org/10.1088/0953-2048/18/2/026
12. Cardwell, D. A., Shi, Y.-H., Hari Babu, N., Pathak, S. K., Dennis, A. R., & lida, K. (2010). Top seeded melt growth of Gd—Ba—Cu—O single grain superconductors. Superconductor Science and Technology, 23(3), 034008. http://doi.org/10.1088/0953-2048/23/3/034008
13. Kim, C.-J., Jee, Y. A., & Hong, G.-W. (2000). Variables affecting the fabrication of single grain YBa2Cu3O7-y superconductors by the top-seeded melt growth process. Superconductor Science and Technology, 13(6), 709-715. http://doi.org/10.1088/0953-2048/13/6/316
14. Zhou, D., Hara, S., Li, B., Xu, K., Noudem, J., & Izumi, M. (2013). Significant improvement of trapped flux in bulk Gd—Ba—Cu—O grains fabricated by a modified top-seeded melt growth process. Superconductor Science and Technology, 26(1), 015003. http://doi.org/10.1088/0953-2048/26/1/015003
15. Muralidhar, M., Jirsa, M., Sakai, N., & Murakami, M. (2003). Progress in melt-processed (Nd Sm Gd)Ba2Cu3Oy superconductors. Superconductor Science and Technology, 16(1), R1-R16. http://doi.org/10.1088/0953-2048/16/1/201
16. Kim, S. J. (2006). Characterization and superconducting properties of (YSN)BCO composites made a top-seeded melt growth process. Journal of Ceramic Processing Research, 7(3), 230-234.
17. Jeong, I. K., Kim, D. Y., Park, Y. K., Lee, K. W., & Park, J. C. (1991). Infiltration-reaction process for fabricating YBa2Cu3O7-δ superconductor. Physica C: Superconductivity, 185-189, 2393-2394. http://doi.org/10.1016/0921-4534(91)91321-T
18. Reddy, E. S., & Rajasekharan, T. (1998). Shape Forming Simultaneous with Jc Enhancement in REBa2Cu3O7 Superconductors. Journal of Materials Research, 13(09), 2472-2475. http://doi.org/10.1557/JMR.1998.0346
19. Devendra Kumar, N., Rajasekharan, T., & Seshubai, V. (2013). Preform optimization in infiltration growth process: An efficient method to improve the superconducting properties of YBa2Cu3O7-x. Physica C: Superconductivity, 495, 55-65. http://doi.org/10.1016/j.physc.2013.07.015
20. Cloots, R., Koutzarova, T., Mathieu, J.-P., & Ausloos, M. (2005). From RE-211 to RE-123. How to control the final microstructure of superconducting single-domains. Superconductor Science and Technology, 18(3), R9-R23. http://doi.org/10.1088/0953-2048/18/3/R01
21. Namburi, D. K., Shi, Y., Palmer, K. G., Dennis, A. R., Durrell, J. H., & Cardwell, D. A. (2016). An improved top seeded infiltration growth method for the fabrication of Y—Ba—Cu—O bulk superconductors. Journal of the European Ceramic Society, 36(3), 615-624. doi:10.1016/j.jeurceramsoc.2015.09.036
22. Hari Babu, N., Kambara, M., Smith, P. J., Cardwell, D. A., & Shi, Y. (2000). Fabrication of Large Single-grain Y—Ba—Cu—O Through Infiltration and Seeded Growth Processing. Journal of Materials Research, 15(06), 1235-1238. http://doi.org/10.1557/JMR.2000.0176
23. Fang, H., Zhou, Y. X., Ravi-Chandar, K., & Salama, K. (2004). On the study of the liquid infiltration and seeded growth process. Superconductor Science and Technology, 17(2), 269-273. http://doi.org/10.1088/0953-2048/17/2/006
24. Yang, W. M., Zhi, X., Chen, S. L., Wang, M., Li, J. W., Ma, J., & Chao, X. X. (2014). Fabrication of single domain GdBCO bulk superconductors by a new modified TSIG technique. Physica C, 496, 1-4. http://doi.org/10.1016/j.physc.2013.06.008
25. Li, G.-Z., Li, J.-W., & Yang, W.-M. (2015). A combined powder melt and infiltration growth technique for fabricating nano-composited Y—Ba—Cu—O single-grain superconductor. Superconductor Science and Technology, 28(10), 105002. http://doi.org/10.1088/0953-2048/28/10/105002
26. Meslin, S., & Noudem, J. G. (2004). Infiltration and top seeded grown mono-domain YBa2Cu3O7-x bulk superconductor. Superconductor Science and Technology, 17(11), 1324-1328. http://doi.org/10.1088/0953-2048/17/11/014
27. Mathieu, J.-P., Koutzarova, T., Rulmont, A., Fagnard, J.-F., Laurent, P., Mattivi, B., Cloots, R. (2005). Investigation of DyBa2Cu3O7-d superconducting domains grown by the infiltration technique starting with small size Dy-211 particles. Superconductor Science and Technology, 18(2), S136-S141. http://doi.org/10.1088/0953-2048/18/2/028
28. Namburi, D. K., Shi, Y., Palmer, K. G., Dennis, A. R., Durrell, J. H., & Cardwell, D. A. (2016). Control of Y-211 content in bulk YBCO superconductors fabricated by a buffer-aided, top seeded infiltration and growth melt process. Superconductor Science and Technology, 29(3), 034007. doi:10.1088/0953-2048/29/3/034007
29. F N Werfel, U Floegel-Delor, R Rothfeld, T Riedel, B Goebel, D Wippich and P Schirrmeister, Superconductor bearings, flywheels and transportation, 2012 Supercond. Sci. Technol. 25 014007, https://doi.org/10.1088/0953-2048/25/1/014007
30. K. Yokoyama, T. Oka, H. Okada, Y. Fujine, A. Chiba, and K. Noto, Solid-Liquid Magnetic Separation Using Bulk Superconducting Magnets, IEEE Transactions on Applied Superconductivity 13 2003 1592-1595, https://doi.org/10.1109/TASC.2003.812799
31. S Nariki, N Sakai and M Murakami, Melt-processed Gd—Ba—Cu—O superconductor with trapped field of 3 Tat 77 K, 2005 Supercond. Sci. Technol. 18 S126, https://doi.org/10.1088/0953-2048/18/2/026
32. M Murakami, Processing of bulk YBaCuO, 1992 Supercond. Sci. Technol. 5 185, https://doi.org/10.1088/0953-2048/5/4/001
33. S Meslin, K lida, N Hari Babu, D A Cardwell and J G Noudem, The effect of Y-211 precursor particle size on the microstructure and properties of Y—Ba—Cu—O bulk superconductors fabricated by seeded infiltration and growth, 2006 Supercond. Sci. Technol. 19 711, https://doi.org/10.1088/0953-2048/19/8/005
34. Yunhua Shi, Tawfique Hasan, Nadendla H. Babu, Felice Torrisi, Silvia Milana, Andrea C. Ferrari and David A. Cardwell, Synthesis of YBa2Cu3O7-δ and Y2BaCuO5 Nanocrystalline Powders for YBCO Superconductors Using Carbon Nanotube Templates, ACS Nano 6, 6, 5395-5403, 10.1021/nn301262t
35. Guo-Zheng Li, Lei Dong, Xiang-Yun Deng, Significant Improvement of Superconducting Properties in Nano-NiFe2O4-Doped Y—Ba—Cu—O Single-Grain Superconductor, J. Am. Ceram. Soc., 99 [2] 388-391 (2016), https://doi.org/10.1111/jace.14035
36. Nahed Moutalbi, Ali M′chirgui, Jacques G. Noudem, Size Effect of Insulating Nano-Inclusions in Y—Ba—Cu—O Bulk Superconductors Fabricated by Seeded Infiltration Growth, Journal of Superconductivity and Novel Magnetism, January 2011, Volume 24, Issue 1-2, pp 365-369, https://doi.org/10.1007/s10948-010-0996-1
37. T. H. Johansen, “Flux-pinning-induced stress and magnetostriction in bulk superconductors,” Supercond. Sci. Technol., vol. 13, no. 10, pp. R121-R137, 2000.
38. Ren, Y., Weinstein, R., Liu, J., Sawh, R. P. and Foster, C. (1995). Damage caused by magnetic pressure at high trapped field in quasi-permanent magnets composed of melt-textured Y—Ba—Cu—O superconductor. Physica C 251 15-26. https://doi.org/10.1016/0921-4534(95)00398-3
39. Fuchs, G., Schätzle, P., Krabbes, G., Gruβ, S., Verges, P., Müller, K.-H., Fink, J. and Schultz, L. (2000). Trapped magnetic fields larger than 14 T in bulk YBa2Cu3O7-x Applied Physics Letters 76 2107. https://doi.org/10.1063/1.126278
40. Krabbes, G, Fuchs G, Canders W-R, May H and Palka R, High temperature superconductor bulk materials: Fundamentals—Processing—Properties Control—Application aspects, 2006, WILEY-VCH Verlag GmbH & Co. KGaA, Germany, Print ISBN:9783527403837|Online ISBN:9783527608041|DOI:10.1002/3527608044, Page 179-189.
41. Devendra K Namburi, John H Durrell, Jan Jaroszynski, Yunhua Shi, Mark Ainslie, Kaiyuan Huang, Anthony R Dennis, Eric E Hellstrom and David A Cardwell, A Trapped Field of 14.3 T in Y—Ba—Cu—O Bulk Superconductors Fabricated by Buffer-Assisted Seeded Infiltration and Growth, Superconductor Science and Technology (in Press)
42. Y.-H. Zhou and H.-D. Yong, “Crack problem for a long rectangular slab of superconductor under an electromagnetic force,” Phys. Rev. B, vol. 76, no. 9, p. 094523, Sep. 2007.
43. Krabbes G, Fuchs G, Verges P, Diko P, Stover G and Gruss S. (2002). 16 T trapped field in modified YBaCuO: materials aspects. Physica C, 378-381, 636-640. https://doi.org/10.1016/S0921-4534(02)01511-3
44. Tomita, M. and Murakami, M. (2003). High-temperature superconductor bulk magnets that can trap magnetic fields of over 17 tesla at 29 K. Nature, 421(6922), 517-520. https://doi:10.1038/nature01350
45. P. Schatzle, G. Krabbes, S. Grub, and G. Fuchs, “YBCO/Ag Bulk Material by Melt Crystallization for Cryomagnetic Applicadions,” IEEE Trans. Applied Supercond., vol. 9, no. 2, pp. 2022-2025, 1999.
46. N Devendra Kumar, T Rajasekharan and V Seshubai, YBCO/Ag composites through a preform optimized infiltration and growth process yield high current densities, 2011 Supercond. Sci. Technol. 24 085005
47. K lida, N H Babu, Y Shi, T Miyazaki, N Sakai, M Murakami and D A Cardwell, Single domain YBCO/Ag bulk superconductors fabricated by seeded infiltration and growth, 2008 J. Phys.: Conf. Ser. 97 012105, https://doi.org/10.1088/1742-6596/97/1/012105
48. Jasmin V J Congreve, Yunhua Shi, Anthony R Dennis, John H Durrell and David A Cardwell, The successful incorporation of Ag into single grain, Y—Ba—Cu—O bulk superconductors, 2018 Supercond. Sci. Technol. 31 035008, https://doi.org/10.1088/1361-6668/aaa831
49. Y Shi, N Hari Babu and D A Cardwell, Development of a generic seed crystal for the fabrication of large grain (RE)-Ba—Cu—O bulk superconductors, 2005 Supercond. Sci. Technol. 18 L13, https://doi.org/10.1088/0953-2048/18/4/L01
50. Devendra K Namburi, Yunhua Shi, Anthony R Dennis, John H Durrell and David A Cardwell, A robust seeding technique for the growth of single grain (RE)BCO and (RE)BCO—Ag bulk superconductors, Supercond. Sci. Technol. 31 (2018) 044003, https://doi.org/10.1088/1361-6668/aaad89
51. Devendra Kumar, N., Shi, Y., Zhai, W., Dennis, A. R., Durrell, J. H., & Cardwell, D. A. (2015). Buffer Pellets for High-Yield, Top-Seeded Melt Growth of Large Grain Y—Ba—Cu—O Superconductors. Crystal Growth & Design, 15(3), 1472-1480. http://doi.org/10.1021/cg501813y
52. T. D. Withnell N. Hari-Babul. Ganney A. Dennis D. A. Cardwell, High-field flux mapping of (RE)BCO bulk superconductors-Development of an in situ scanning system, Materials Science and Engineering: B, Volume 151, Issue 1, 15 Jun. 2008, Pages 79-83, https://doi.org/10.1016/j.mseb.2008.02.016
53. Fairhurst C. (1964) On the validity of the ‘Brazilian’ test for brittle materials, Int. J. Rock Mech. Mining Sci. Geomech., 1(4), 535-446. https://doi.org/10.1016/0148-9062(64)90060-9
54. Andreev G. E. (1991). A review of the Brazilian test for rock tensile strength determination. Mining Science and Technology, 13 445-456. https://doi.org/10.1016/0167-9031(91)91006-4
55. Kai Yuan Huang, Difan Zhou, Jan Srpčič, Yunhua Shi, Devendra K. Namburi, A. Dennis, Mark D. Ainslie, Martin Boll, Roman Bause, Mykhaylo Filipenko, John H. Durrell and David A. Cardwell (2018) Spatial Distribution of Flexural Strength in Y—Ba—Cu—O Bulk Superconductors, IEEE Transactions on Applied Superconductivity, 28(4), 6801505. https://doi.org/10.1109/TASC.2018.2814055
56. A Koblischka-Veneva, F Mücklich1, M R Koblischka2, N Hari Babu3, D A Cardwell3 and M Murakami4, Grain orientations and distribution of Y2Ba4CuUOx phase in melt-textured YBCO with addition of depleted uranium oxide studied by EBSD, 2006 Supercond. Sci. Technol. 19 S567
57. N. Hari Babu, K. lida and D. A. Cardwell, Enhanced magnetic flux pinning in nano-composite Y—Ba—Cu—O superconductors, Physica C: Superconductivity and its Applications, Volumes 445-448, 1 Oct. 2006, Pages 353-356, https://doi.org/10.1016/j.physc.2006.04.081

1. A bulk superconductor device comprising a single grain RE-BCO element incorporating reinforcing fibres.

2. The bulk superconductor device according to claim 1 wherein the single grain (RE)BCO element comprises RE-211 pinning sites disposed in a RE-123 matrix.

3. The bulk superconductor device according to claim 1 wherein the single grain (RE)BCO element further comprises Ag.

4. The bulk superconductor device according to claim 1 wherein the single grain RE-BCO element further comprises a grain refining agent.

5. The bulk superconductor device according to claim 4 wherein the grain refining agent is selected from Pt or CeO₂.

6. The bulk superconductor device according to claim 1 wherein the reinforcing fibres comprise a ceramic.

7. The bulk superconductor device according to claim 1 wherein the reinforcing fibres comprise a refractory metal.

8. The bulk superconductor device according to claim 1 wherein the reinforcing fibres comprise a refractory metal core and a ceramic cladding surrounding the core.

9. The bulk superconductor device according to claim 6 wherein the ceramic is SiC.

10. The bulk superconductor device according to claim 7 wherein the refractory metal is W.

11. The bulk superconductor device according to claim 1 wherein the element has a minimum linear dimension of at least 5 mm.

12. The bulk superconductor device according to claim 1 wherein the element has a maximum linear dimension of at least 50 mm.

13. The bulk superconductor device according to claim 1 wherein the element has a volume of at least 1500 mm³.

14. The bulk superconductor device according to claim 1 wherein the reinforcing fibres have a length of at least 1 mm, more preferably at least 5 mm.

15. The bulk superconductor device according to claim 1 further comprising external reinforcement.

16. The bulk superconductor device according to claim 15 wherein the external reinforcement is selected from one or more of:
resin and/or fibre reinforced resin reinforcement;
metallic jacket reinforcement; and
shrink-fit reinforcement.

17. A method of manufacturing a bulk superconductor device, the method comprising:
providing a precursor powder;
providing reinforcing fibres;
forming a precursor body from the precursor powder and the reinforcing fibres; and
subjecting the precursor body to melt processing to form a single grain RE-BCO element incorporating the reinforcing fibres.

18. The method according to claim 17 wherein the single grain RE-BCO element comprises RE-211 pinning sites disposed in a RE-123 matrix.

19. The method according to claim 17 wherein the melt processing is a top seeded melt growth process.

20. The method according to claim 17 wherein the precursor powder comprises a mixture of RE-123 and RE-211.

21. The method according to claim 17 wherein the melt processing is a top seeded infiltration growth process in which the precursor body is disposed on a liquid source precursor.

22. The method according to claim 21 wherein the precursor powder comprises RE-211.

23. The method according to claim 17 wherein a buffer pellet is disposed between a seed crystal and the precursor body during melt processing.
